(19) United States
(12) Patent Application Publication
(10) Pub. No.: US 2008/0164619 A1
(43) Pub. Date: Jul. 10, 2008

(54) Semiconductor chip package and method of manufacturing the same

(75) Inventors: Cheol-Woo Lee, Asan-si (KR); Bo-Seong Kim, Seoul (KR); Kwang-Ryul Lee, Suwon-si (KR); Tae-Young Lee, Hongcheon-gun (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/007,188

(22) Filed: Jan. 8, 2008

(30) Foreign Application Priority Data
Jan. 8, 2007 (KR) 10-2007-0001954

(51) Int. Cl. H01L 23/538; H01L 21/56

(52) U.S. Cl. 257/777; 438/118; 257/E23.169; 257/E21.502

(57) ABSTRACT

Provided are a semiconductor chip package and a method of manufacturing the semiconductor package. The semiconductor chip package may include at least one semiconductor chip, whose upper surface includes a plurality of electrode pads on a substrate including a conductive pattern, and the conductive pattern and the electrode pads of the chip are connected electrically using a bonding wire. After a first insulation member is provided to an upper surface of the at least one semiconductor chip, the semiconductor chip package may be formed by providing a second insulation member in contact with the first insulation member, the bonding wires, and the at least one semiconductor chip.

### PRIORITY STATEMENT

This application claims priority under 35 U.S.C. § 119 from Korean Patent Application No. 2007-1954, filed on Jan. 8, 2007 in the Korean Intellectual Property Office (KIPO), the entire contents of which are herein incorporated by reference.

### BACKGROUND

1. Field

Example embodiments relate to a semiconductor chip package and a method of manufacturing the same. Other example embodiments relate to a semiconductor chip package for sealing a semiconductor chip in order to singularize the semiconductor chip, and a method of manufacturing the semiconductor chip.

2. Description of the Related Art

A semiconductor device is manufactured by a fabrication process for forming an electrical circuit including electrical devices on a silicon wafer used as a semiconductor substrate, an electrical die sorting (EDS) process for testing electrical characteristics of semiconductor devices formed in the fabrication process, and a packaging process for singularizing and sealing each of the semiconductor devices with epoxy resin.

FIG. 1 is a cross-sectional view illustrating a conventional semiconductor chip package. Referring to FIG. 1, a semiconductor chip package 1 includes a substrate 10 where a conductive pattern is formed, chips 20 and 30 stacked on the substrate 10, bonding wires 40 and 50 connecting the chips 20 and 30 to the conductive pattern, and an insulation member 60 molded on the substrate 10 to protect the bonding wires 40 and 50 and the chips 20 and 30. The insulation member 60 may be formed by contacting a molding die with the substrate 10 while the chips 20 and 30 and the bonding wires 40 and 50 are provided on the substrate 10, and filling the molding die with a molding resin. In the process of forming the insulation member 60, when a space between an upper chip 30 and the molding die is relatively small, the molding resin may not flow easily through the space between the molding die and the upper chip 30 due to the viscosity of the molding resin. Therefore, the insulation member 60 may be incompletely formed. Further, due to a difference between the velocity of the molding resin flowing through the space between the molding die and the upper chip 30 and the velocity of the molding resin flowing through a space between the molding die and the substrate 10, the bonding wires 40 and 50 may be separated from the chips 20 and 30 and the conductive pattern.

In the process of forming the insulation member 60, when the space between the upper chip 30 and the molding die is enlarged, the thickness of the semiconductor chip package 1 may become thicker.

### SUMMARY

Example embodiments provide a semiconductor chip package that is capable of preventing or reducing failures of a bonding wire and an insulation member. Example embodiments provide a method of manufacturing a semiconductor chip package.

Example embodiments may include a semiconductor chip package, at least one semiconductor chip, bonding wires, a first insulation member and/or a second insulation member. A conductive pattern may be on the substrate. The at least one semiconductor chip may be on the substrate. Further, a plurality of electrode pads may be on an upper face of the at least one semiconductor chip. The bonding wires may electrically connect the conductive pattern to the electrode pads of the at least one semiconductor chip. The first insulation member may be provided on any surface, for example, an upper face of the at least one semiconductor chip. The second insulation member may be provided on the substrate to contact the first insulation member, the bonding wires, the at least one semiconductor chip, and/or the first insulation member.

According to example embodiments, the first insulation member may act as an insert. According to example embodiments, the first insulation member may have a plate shape. According to example embodiments, the first insulation member may be provided to cover the bonding wires on the upper surface of the at least one semiconductor chip.

According to example embodiments, the semiconductor chip package may additionally include an adhesive layer interposed between the at least one semiconductor chip and the first insulation member to adhere the first insulation member to the at least one semiconductor chip.

According to example embodiments, the first insulation member and the second insulation member may have a coplanar surface.

According to example embodiments, the first insulation member and the second insulation member may include an epoxy molding compound.

Example embodiments are directed to a method of manufacturing a semiconductor package including at least one semiconductor chip, whose upper surface may include a plurality of electrode pads. The plurality of electrode pads may be on a substrate where a conductive pattern may be formed. The electrode pads of the at least one semiconductor chip and the conductive pattern may be connected electrically to each other using a bonding wire. A first insulation member may be provided on any surface, for example, an upper surface of the at least one semiconductor chip. The first insulation member, the bonding wires and/or the at least one semiconductor chip on the substrate may be covered or in contact with a second insulation member to form the semiconductor chip package.

According to example embodiments, the first insulation member may be provided to cover the bonding wire on the upper surface of the at least one semiconductor chip. According example embodiments, the first insulation member may be attached on the upper surface of the at least one semiconductor chip using an adhesive material. According to example embodiments, the second insulation member may be formed to have an upper surface coplanar with that of the first insulation member. According to example embodiments, the first insulation member and the second insulation member may include an epoxy molding compound. According to example embodiments, contacting and/or covering the first insulation member, the bonding wires and/or the at least one semiconductor chip on the substrate with the second insulation member may include providing a die that makes contact with an upper surface of the first insulation member and a lower surface of the substrate, filling the inside of the die with a liquid insulation material, and removing the die.

According to example embodiments, a viscous insulation material may not be necessary because a first insulation member may be provided on at least one semiconductor chip and the die makes contact with the first insulation member. A viscous insulation material may be used for forming the second insulation member, everywhere, except where the first insulation member is located. Therefore, molding defects in the second insulation member, due to restricted flow of the insulation material through a space at least partially defined by the at least one semiconductor chip, may not be generated. When the insulation material flows at a more uniform velocity inside the die, defects in the bonding wire due to velocity difference of the insulation material may be prevented or reduced. By providing a relatively thin first insulation member, the thickness of the semiconductor chip package may be reduced.

### BRIEF DESCRIPTION OF THE DRAWINGS

Example embodiments will be more clearly understood from the following detailed description taken in conjunction with the accompanying drawings. FIGS. 1-3E represent non-limiting, example embodiments as described herein.

FIG. 1 is a cross-sectional view illustrating a conventional semiconductor chip package;

FIG. 2 is a cross-sectional view illustrating a semiconductor chip package according to example embodiments; and

FIGS. 3A to 3E are cross-sectional views illustrating a method of manufacturing the semiconductor chip package illustrated in FIG. 2.

### DETAILED DESCRIPTION OF EXAMPLE EMBODIMENTS

Example embodiments are described more fully hereinafter with reference to the accompanying drawings, in which example embodiments are shown. Example embodiments may, however, be embodied in many different forms and should not be construed as limited to example embodiments set forth herein. Rather, example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of the example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

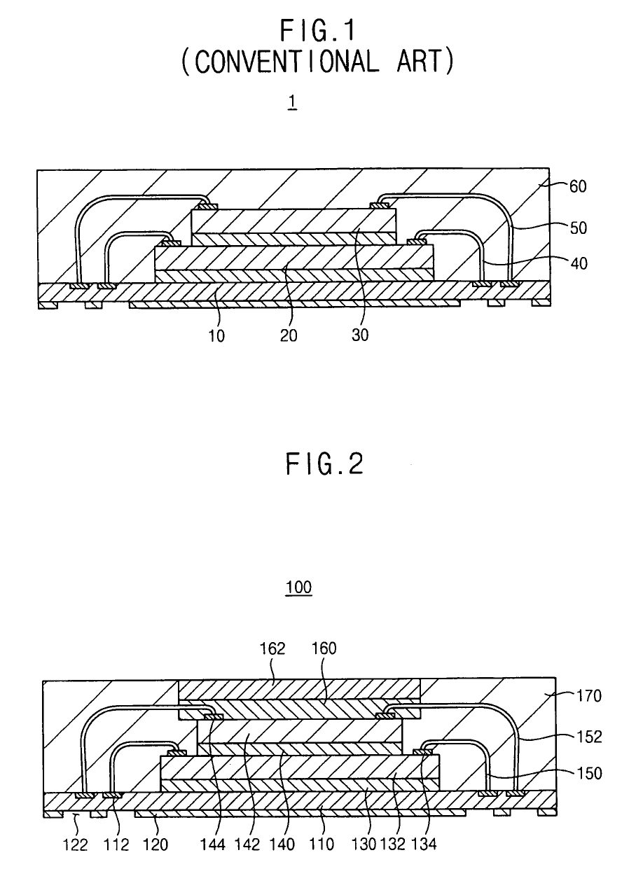

FIG. 2 is a cross-sectional view illustrating a semiconductor chip package according to example embodiments. Referring to FIG. 2, a semiconductor chip package 100 may include a substrate 110, an insulation layer 120, a first adhesive layer 130, a first semiconductor chip 132, a second adhesive layer 140, a second semiconductor chip 142, a first bonding wire 150, a second bonding wire 152, a third adhesive layer 160, a first insulation member 162 and/or a second insulation member 170.

The substrate 110 may include a conductive pattern 112. Examples of the substrate 110 may include a printed circuit board (PCB), a tape circuit substrate and/or, a ceramic substrate. The insulation layer 120 may be provided on a lower surface of the substrate 110. The insulation layer 120 may have a plurality of openings 122 exposing solder balls (not shown) mounted to the substrate 110. The insulation layer 120 may include an insulation material. Examples of the insulation material may include polyimide or a similar material.

The first semiconductor chip 132 may be provided on the substrate 110. A plurality of first electrode pads 134 may be provided on an upper surface of the first semiconductor chip 132. The first electrode pads 134 may be arranged along edges of the upper surface of the first semiconductor chip 132.

The first adhesive layer 130 may be interposed between an upper surface of the substrate 110 and a lower surface of the first semiconductor chip 132. Therefore, the first semiconductor chip 132 may be fixed on the substrate 110. The first adhesive layer 130 may include an insulation material. Examples of the first adhesive layer 130 may include epoxy, an adhesive and/or a tape.

The second semiconductor chip 142 may be provided on the first semiconductor chip 132. A plurality of second electrode pads 144 may be provided on an upper surface of the second semiconductor chip 142. The second electrode pads 144 may be arranged along edges of the upper surface of the second semiconductor chip 142. According to example embodiments, as illustrated in FIG. 2, the second semiconductor chip 142 may be smaller in size than the first semiconductor chip 132. According to other example embodiments, the second semiconductor chip 142 may be substantially the same size as the first semiconductor chip 132 or larger than the first semiconductor chip 132.

The second adhesive layer 140 may be interposed between an upper surface of the first semiconductor chip 132 and a lower surface of the semiconductor chip 142. Therefore, the second semiconductor chip 142 may be attached to the first semiconductor chip 132. The second adhesive layer 140 may be the same as the first adhesive layer 130. Thus, any further illustrations with respect to the second adhesive layer 140 are omitted herein for brevity.

The first bonding wire 150 may electrically connect the first electrode pads 134 of the first semiconductor chip 132 with the conductive pattern 112 of the substrate 110. The second bonding wire 152 may electrically connect the second electrode pads 144 of the second semiconductor chip 142 with the conductive pattern 112 of the substrate 110. Examples of the first and second bonding wires 150 and 152 may include a gold (Au) wire and an aluminum (Al) wire.

The first insulation member 162 may be provided on the second semiconductor chip 142. The first insulation member 162 may include an insulation material. Further, the first insulation member 162 may have a plate shape. Examples of the insulation material may include an epoxy molding compound or a similar material. According to example embodiments, as illustrated in FIG. 2, the first insulation member 162 may be substantially the same size as the second semiconductor chip 142 or larger than the second semiconductor chip 142. Therefore, the first insulation member 162 may be on or cover the second electrode pads 144 on the second semiconductor chip 142 and a portion of the second bonding wires 152. According to other example embodiments, the first insulation member 162 may be smaller than the second semiconductor chip 142. For example, the first insulation member 162 may not cover the second electrode pads 144 on the second semiconductor chip 142 and the second bonding wires 152.

The third adhesive layer 160 may be interposed between an upper surface of the second semiconductor chip 142 and a lower surface of the first insulation member 162. Therefore, the first insulation member 162 may be attached to the second semiconductor chip 142. Examples of the third adhesive layer 160 may include epoxy, an adhesive and/or a tape. According to example embodiments, when the first insulation member 162 is substantially the same size or larger than the second semiconductor chip 142, the third adhesive layer 160 may include a tape into which the second electrode pads 144 and the second bonding wires 152 may penetrate. For example, even though the third adhesive layer 160 covers or is on the second electrode pads 144 and the second bonding wires 152, the third adhesive layer 160 may maintain a flat shape, without changing into a convex shape due to the second bonding wires 152 and the second electrode pads 144. Therefore, the first insulation member 162 may also maintain a flat shape. According to example embodiments, when the first insulation member 162 is smaller than the second semiconductor chip 142, the third adhesive layer 160 may include a conventional tape.

The second insulation member 170 may be provided on an upper surface of the substrate 110 to cover or be on the first semiconductor chip 132, the second semiconductor chip 142, the first bonding wire 150, the second bonding wire 152, and the first insulation member 162. The second insulation member 170 may cover or be on side faces and a bottom face of the first insulation member 162 and/or the third adhesive layer 160. The second insulation member 170 may have an upper surface coplanar with that of the first insulation member 162. The first insulation member 162 and the second insulation member 170 may protect the first semiconductor chip 132, the second semiconductor chip 142, the first bonding wire 150, and second bonding wire 152 from the external environment, e.g., shock. Examples of the second insulation member 170 may include glop-top and/or an epoxy molding compound.

Although the semiconductor chips 132 and 142 are illustrated as being stacked on the substrate 110, and the first insulation member 162 is illustrated as being provided on the second semiconductor chip 142 located in an upper position in example embodiments, according to other example embodiments, one semiconductor chip may be provided on a substrate, and a first insulation member may be provided on the semiconductor chip.

According to example embodiments, the semiconductor chip package 100 may prevent or reduce defects that occur when a second insulation member is sealed because a first insulation member having a plate shape may be provided on an upper-positioned semiconductor chip.

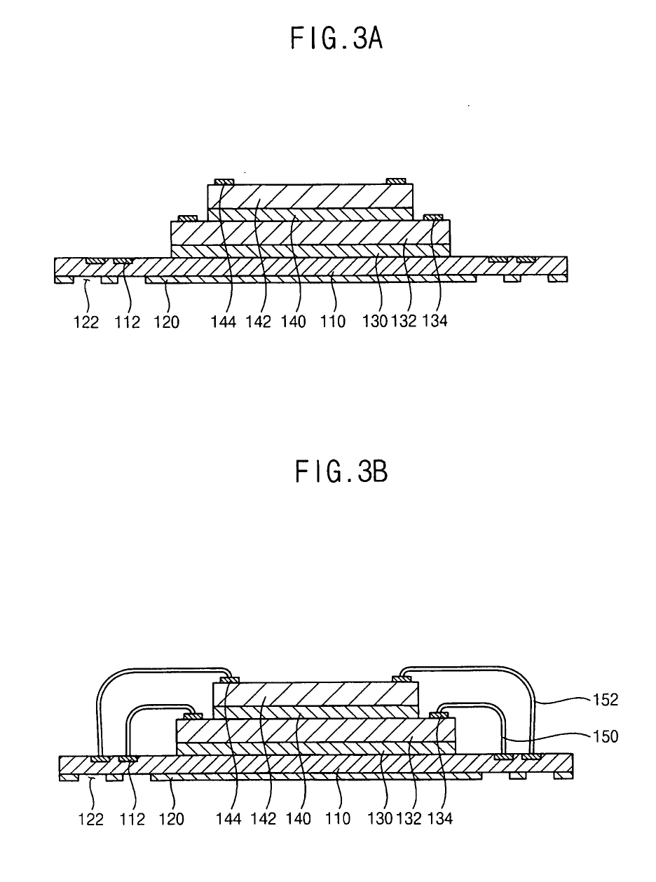

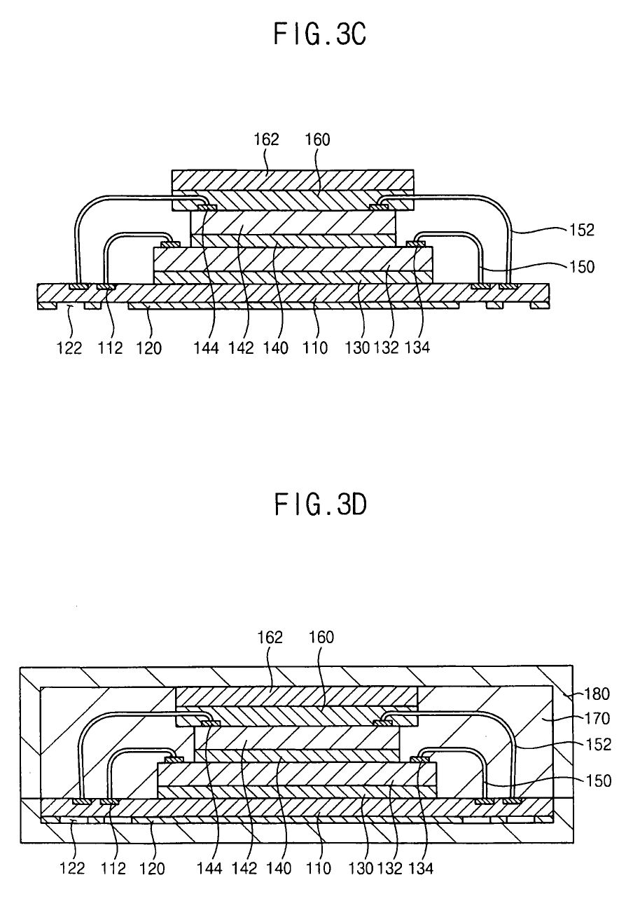

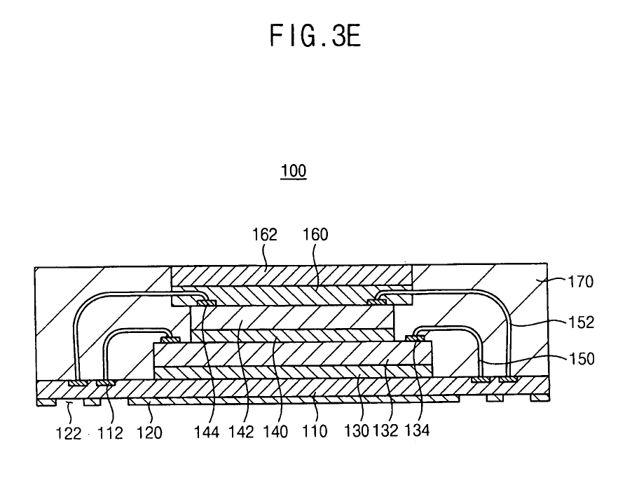

FIGS. 3A to 3E are cross-sectional views illustrating a method of manufacturing the semiconductor chip package illustrated in FIG. 2. Referring to FIG. 3A, a substrate 110 having a conductive pattern 112 may be prepared. An insulation layer 120 may be formed on a lower surface of the substrate. The insulation layer 120 may be formed by coating polyimide or attaching polyimide tape on the lower surface of the substrate. A plurality of openings 122 may be formed by removing selectively a portion of the insulation layer 120 where solder balls (not shown) may be mounted. The removal of the insulation layer 120 may be performed by a chemical etching process and/or a laser etching process.

According to example embodiments, although the insulation layer 120 is illustrated to be formed on the substrate 110 before a manufacturing process of a semiconductor chip package, the insulation layer 120 may be formed on the substrate 110 after the manufacturing process of the semiconductor chip package is completed.

A first semiconductor chip 132 may be attached to an upper surface of the substrate 110 using a first adhesive layer 130, e.g., epoxy, an adhesive, and/or a tape. The first electrode pads 134 may be positioned on an upper surface of the first semiconductor chip 132.

A second semiconductor chip 142 may be attached to the upper surface of the first semiconductor chip 132 using a second adhesive layer 140. Second electrode pads 144 may be positioned on an upper surface of the second semiconductor chip 142.

Referring to FIG. 3B, the first electrode pads 134 of the first semiconductor chip 132 may be connected with a conductive pattern 112 of the substrate 110 using first bonding wires 150. Further, the second electrode pads 144 of the second semiconductor chip 142 may be connected with the conductive pattern 112 of the substrate 110 using second bonding wires 152. The first and second electrode pads 134 and 144 may be connected with the conductive patterns 112 electrically through the first and second bonding wires 150 and 152. Examples of the first bonding wire 150 and the second bonding wire 152 may include a gold (Au) wire and/or an aluminum (Al) wire.

Referring to FIG. 3C, a first insulation member 162 may be attached to an upper surface of the second semiconductor chip 142 using a third adhesive layer 160, e.g., epoxy, an adhesive, and/or a tape. The first insulation member 162 may be formed by processing an insulation material, e.g., an epoxy molding compound into a plate shape. According to example embodiments, as illustrated in FIG. 3C, the first insulation member 162 covers connecting portions of the second bonding wires 152 and the second electrode pads 144. According to example embodiments, the first insulation member 162 may not be on or cover the connecting portions of the second bonding wires 152 and the second electrode pads 144.

Referring to FIG. 3D, a die 180 for forming the second insulation member 170 may be provided. The die 180 may be adjacent to the insulation layer 120 beneath the substrate 110, and may be adjacent to an upper surface of the first insulation member 162.

An insulation material may be provided inside the die 180. Examples of the insulation material may include a liquid encapsulant, and/or an epoxy molding compound. When the first insulation member 162 is provided on the second semiconductor chip 142 and the die 180 is adjacent to the upper surface of the first insulation member 162, an insulation material for forming the second insulation member 170 may not be provided through a space over the first semiconductor chip 142. Therefore, molding defects in the second insulation member 170, which occur due to restricted flow of the insulation material through the space over the first semiconductor chip 142, may be prevented or reduced. Further, the insulation material provided inside the die 180 may flow at a uniform velocity without velocity differences due to position. Therefore, separation of the first bonding wire 150, the second bonding wire 152 from the first electrode pad 134, the second electrode pad 144 and the conductive pattern 112 due to the velocity differences of the insulation material may be reduced or prevented. The insulation material provided inside the die 180 may be hardened to form a second insulation member 170.

Referring to FIG. 3E, after the insulation material provided inside the die 180 is hardened, the second insulation member 170 may be formed by removing the die 180. Therefore, the second insulation member 170 may be provided on an upper surface of the substrate 110, covering or on the first semiconductor chip 132, the second semiconductor chip 142, the first bonding wire 150, the second bonding wire 152, and the first insulation member 162. The first insulation member 162 and the second insulation member 170 may protect the first semiconductor chip 132, the second semiconductor chip 142, the first bonding wire 150, and the second bonding wire 152 from the external environment, e.g., shock.

A semiconductor chip package 100 may be completed by forming the second insulation member 170. Because the second insulation member 170 may be formed with the die 180 in contact with an upper surface of the first insulation member 162, an upper surface of the second insulation member 170 may be coplanar with the upper surface of the first insulation member 162. By forming the first insulation member 162 to be relatively thin, a thickness of the semiconductor chip package 100 may be reduced.

Solder balls may be mounted to the conductive pattern 112 of the substrate 110 exposed by the insulation layer 120. The substrate 110 may be loaded into a relatively high temperature furnace or a similar heating apparatus to firmly attach the solder ball on the conductive pattern 112.

As mentioned above, according to example embodiments, a first insulation member may be provided on a semiconductor chip on a substrate and a die may be provided adjacent to the first insulation member. Therefore, an insulation material to form a second insulation member may not be provided into a space over the semiconductor chip. Molding defects in the second insulation member due to restricted flow of the insulation material through space over the semiconductor chip may be prevented or reduced. Bonding wire defects due to velocity differences of the insulation material may be prevented or reduced because the insulation material may flow at a uniform velocity inside the die with no relation to position.

An upper surface of the second insulation member may have a height the same as the height of the upper surface of the first insulation member because the second insulation member may be formed with the die in contact with an upper surface of the first insulation member. By forming the first insulation member to be relatively thin, the thickness of the semiconductor chip package may be reduced.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A semiconductor chip package comprising:
a substrate including a conductive pattern;
at least one semiconductor chip, whose upper surface includes a plurality of electrode pads, on the substrate;
bonding wires electrically connecting the conductive pattern to the plurality of electrode pads of the at least one semiconductor chip;
a first insulation member on at least a portion of the upper surface of the at least one semiconductor chip; and
a second insulation member on the substrate to cover the bonding wires and the at least one semiconductor chip.

2. The semiconductor chip package of claim 1, wherein the first insulation member has a plate shape.

3. The semiconductor chip package of claim 1, wherein the first insulation member covers the bonding wire on the upper surface of the at least one semiconductor chip.

4. The semiconductor chip package of claim 1, further comprising; at least one adhesive layer between the at least one semiconductor chip and the first insulation member to attach the first insulation member to the at least one semiconductor chip.

5. The semiconductor chip package of claim 1, wherein the first insulation member and the second insulation member have a substantially coplanar upper surface.

6. The semiconductor chip package of claim 1, wherein the first insulation member and the second insulation member include an epoxy molding compound.

7. The semiconductor chip package of claim 1, wherein the substrate a printed circuit board, a tape circuit substrate, and ceramic substrate.

8. The semiconductor chip package of claim 1, further comprising:
an insulation layer on a lower surface of the substrate.

9. The semiconductor chip package of claim 1:
wherein the at least one semiconductor chip includes a first semiconductor chip, on whose upper surface a plurality of first electrode pads is formed, on the substrate and a second semiconductor chip, on whose upper surface a plurality of second electrode pads is formed, on the first semiconductor chip; and
wherein the bonding wires include first bonding wires electrically connecting the conductive pattern to the first electrode pads of the first semiconductor chip and second bonding wires electrically connecting the conductive pattern to the second electrode pads of the second semiconductor chip.

10. The semiconductor chip package of claim 9, further comprising:
a first adhesive layer between the first semiconductor chip and substrate and a second adhesive layer between the first semiconductor chip and the second semiconductor chip.

11. A method of manufacturing a semiconductor chip package, comprising:
mounting at least one semiconductor chip, whose upper surface includes a plurality of electrode pads, on a substrate including a conductive pattern;
electrically connecting the plurality of electrode pads of the at least one semiconductor chip to the conductive pattern using a bonding wire;
providing a first insulation member on the upper surface of the at least one semiconductor chip; and
providing a second insulation member in contact with the first insulation member, the bonding wires, and the at least one semiconductor chip.

12. The method of claim 7, wherein the first insulation member covers the bonding wire on the upper surface of the at least one semiconductor chip.

13. The method of claim 7, wherein the first insulation member is attached to the upper surface of the at least one semiconductor chip using an adhesive material.

14. The method of claim 7, wherein the second insulation member has an upper surface coplanar with that of the first insulation member.

15. The method of claim 7, wherein the first insulation member and the second insulation member includes an epoxy molding compound.

16. The method of claim 7, wherein providing a second insulation member in contact with the first insulation member, the bonding wires, and the at least one semiconductor chip includes
providing a die that makes contact with an upper surface of the first insulation member and a lower surface of the substrate;
providing a liquid insulation material inside the die; and
removing the die.
